(19) United States
(12) Patent Application Publication
(10) Pub. No.: US 2012/0273950 A1
(43) Pub. Date: Nov. 1, 2012

(54) INTEGRATED CIRCUIT STRUCTURE INCLUDING COPPER-ALUMINUM INTERCONNECT AND METHOD FOR FABRICATING THE SAME

(75) Inventors: Kuo Hui Su, Taipei City (TW); Yi Nan Chen, Taipei City (TW); Hsien Wen Liu, Luzhu Township (TW)

(73) Assignee: NANYA TECHNOLOGY CORPORATION, Kueishan (TW)

(21) Appl. No.: 13/095,209

(22) Filed: Apr. 27, 2011

(51) Int. Cl. H01L 23/485; H01L 21/283

(52) U.S. Cl. 257/751; 438/653; 257/E23.019; 257/E21.159

(57) ABSTRACT

An integrated circuit structure including a copper-aluminum interconnect with a CuSiN layer and a method for fabricating the same are provided. The method for fabricating an integrated circuit structure including a copper-aluminum interconnect according to the present invention comprises the steps of providing a copper (Cu) layer; forming a barrier layer including a CuSiN layer on the copper layer; forming a wetting layer on the barrier layer; and forming an aluminum (Al) layer on the wetting layer.

### BACKGROUND

1. Technical Field

The present invention relates to an integrated circuit structure including a copper-aluminum interconnect and a method for fabricating the same, and more particularly, to an integrated circuit structure including a to copper-aluminum interconnect with a CuSiN layer and a method for fabricating the same.

2. Background

In the fabrication of integrated circuit structures, aluminum (Al) and its alloys are widely used for forming electrical connections. However, advances in device miniaturization have concomitantly resulted in expansion of the number of devices which must be electrically interconnected, which in turn require advanced integrated circuit designs necessitating extremely narrow interconnect leads. Utilizing aluminum and its alloys for high density interconnect formation raises problems with Al gap fill such as via undercut and overhung structure.

In order to mend a via undercut in an integrated circuit structure, the bottom and corner step coverage in a traditionally-used barrier layer (such as TiOx+TiN or Ta/TaN formed by the physical vapor deposition process, PVD) need to be improved. However, increasing the bottom and corner step coverage in a barrier layer leads to more severe problems with overhung on the top via, which, in the worst case, could cause Al gap fill fail.

Conventional approaches to prevent Al gap fill issues, involve reducing barrier thickness or increasing barrier layer bias power so as to mitigate the overhung issue. However, other side effects remain at issue, such as overly thin barrier layer causing Al/Cu intermixture, or increasing bias power causing poor via corner step coverage.

### SUMMARY

One aspect of the present invention provides an integrated circuit structure including a copper-aluminum interconnect to reduce the barrier thickness and prevent gap fill problems such as overhung and other side effects. An integrated circuit structure including a copper-aluminum interconnect according to this aspect of the present invention comprises a copper (Cu) layer, a barrier layer including a CuSiN layer, an aluminum (Al) layer and a wetting layer. The barrier layer is disposed on the copper layer. The aluminum (Al) layer is disposed over the barrier layer. The wetting layer is disposed between the barrier layer and the aluminum (Al) layer.

Another aspect of the present invention provides a method for fabricating an integrated circuit structure including a copper-aluminum interconnect to reduce the barrier thickness and prevent gap fill problems such as overhung and other side effects. A method for fabricating an integrated circuit structure including a copper-aluminum interconnect according to this aspect of the present invention comprises the steps of providing a copper (Cu) layer; forming a barrier layer including a CuSiN layer on the copper layer; forming a wetting layer on the barrier layer; and forming an aluminum (Al) layer on the wetting layer.

Another aspect of the present invention provides a method for fabricating an integrated circuit structure including a copper-aluminum interconnect to reduce the barrier thickness and prevent gap fill problems such as overhung and other side effects. A method for fabricating an integrated circuit structure including a copper-aluminum interconnect according to this aspect of the present invention comprises the steps of forming a second dielectric layer on a first dielectric layer and a copper layer in the first dielectric layer to form a hole exposing the copper layer; forming a barrier layer including a CuSiN layer on the exposed copper layer; forming a wetting layer on the barrier layer; and forming an aluminum (Al) layer in the hole and on the wetting layer.

The foregoing outlines rather broadly the features of the present invention in order that the detailed description of the invention to follow may be better understood. Additional features of the invention will be described hereinafter and form the subject of the claims of the invention. It should be appreciated by those skilled in the art that the concept and specific to embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives of the present invention will become apparent upon reading the following description and upon reference to the accompanying drawings in which:

FIG. 1 is a schematic view illustrating an integrated circuit structure including a copper-aluminum interconnect with a barrier layer including a CuSiN layer according to one embodiment of the present invention;

FIG. 2 and FIG. 5 illustrate a method for fabricating an integrated circuit structure according to one embodiment of the present invention; and

FIG. 6 is a schematic view illustrating another integrated circuit structure including a copper-aluminum interconnect with a barrier layer including a CuSiN layer according to one embodiment of the present invention.

### DETAILED DESCRIPTION

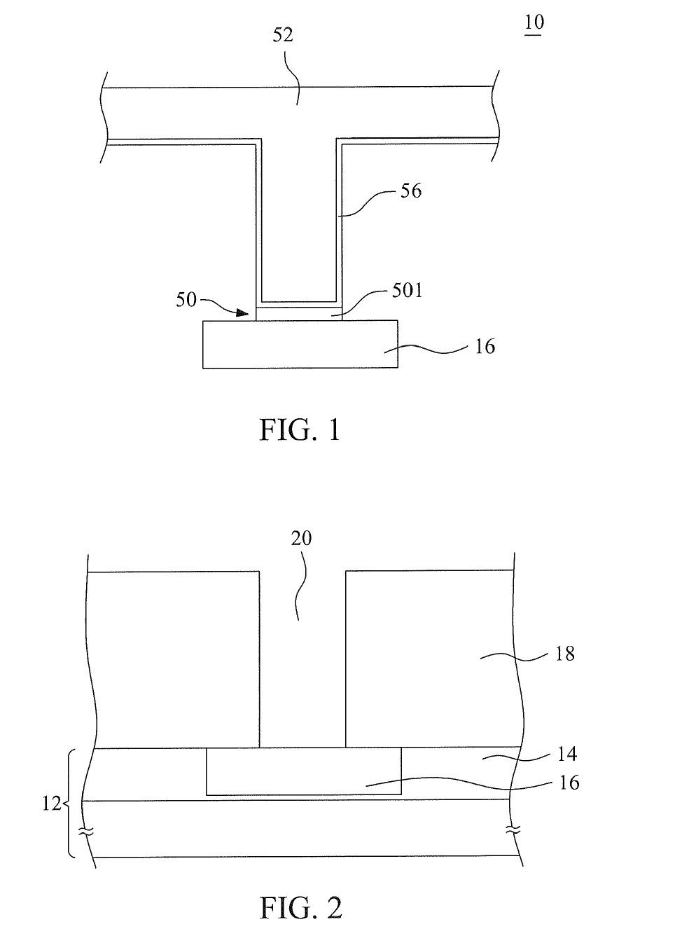

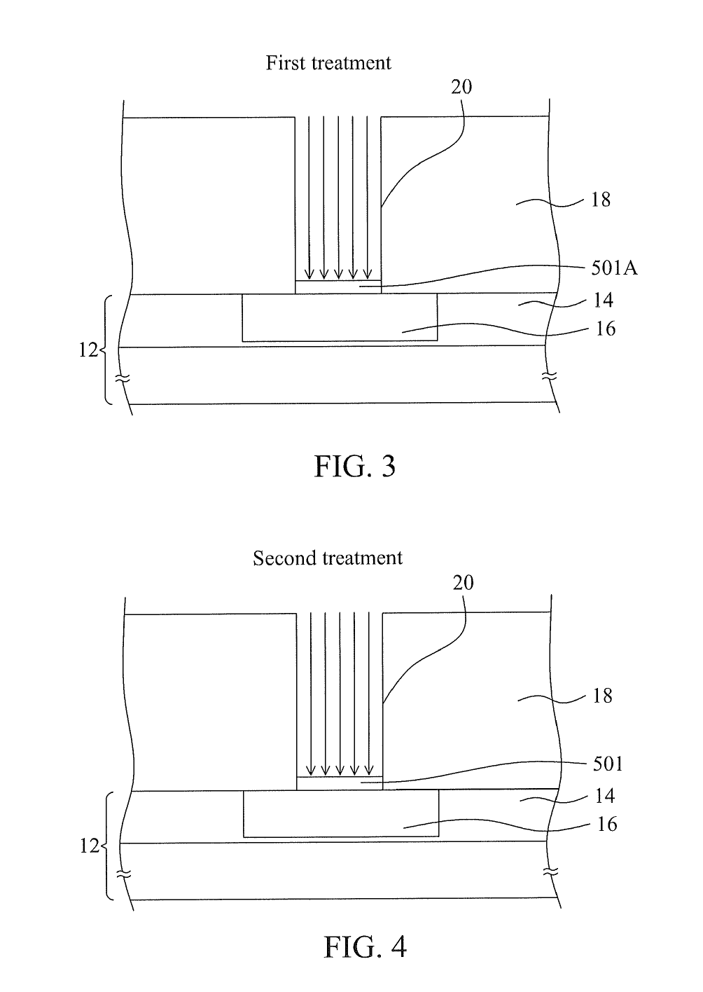

FIG. 1 is a schematic view illustrating a copper-aluminum interconnect according to one embodiment of the present invention. FIG. 2 to FIG. 5 illustrate a method for fabricating an integrated circuit structure according to one embodiment of the present invention. In the embodiment illustrated by FIG. 1, the copper-aluminum interconnect 10 comprises a copper (Cu) layer 16, a barrier layer 50 including a CuSiN layer 501, a wetting layer 56 and an aluminum (Al) layer 52. The CuSiN layer 501 is a conductive layer. The barrier layer 50 is disposed on the copper layer 16. The aluminum layer 52 is disposed over the barrier layer 50. The wetting layer 56 is disposed between the barrier layer 50 and the aluminum (Al) layer 52.

Referring to FIG. 1 to FIG. 5, in one embodiment of the present invention, the integrated circuit structure 100 includes the copper-aluminum interconnect 10, a first dielectric layer 14, a second dielectric layer 18 and a wetting layer 56. The copper layer 16 is disposed in the first dielectric layer 14, the second dielectric layer 18 is disposed on the first dielectric layer 14 and the copper layer 16 and forms a hole 20 exposing the copper layer 16, and the barrier layer 50 covers the hole 20. The barrier layer 50 including the CuSiN layer 501 is disposed on the copper layer 16 and forms a recess 503. The aluminum (Al) layer 52 is disposed in the recess 503 and on the wetting layer 56.

In one embodiment of the present invention, the second dielectric layer 18 is formed on a substrate 12 including the copper layer 16 in the first dielectric layer 14, and the hole 20 exposing the copper layer 16 is then formed in the second dielectric layer 18 by the photolithographic and etching processes. The substrate 12 may further include a silicon substrate, conductor and insulator below the first dielectric layer 14, which are prepared in advance of forming the copper layer 16. Subsequently, the barrier layer 50 is formed inside the hole 20 and covers the exposed copper layer 16, so as to form the recess 503. The wetting layer 56, such as a titanium layer, covers the barrier layer 50 and the sidewall of the hole 20, and the aluminum (Al) layer 52 is then disposed in the recess 503 and on the aluminum (Al) layer 52 (correspondingly over the copper layer 16), as shown in FIG. 5. The barrier layer 50 covering the bottom surface and the sidewall of the hole 20 can prevent reciprocal diffusion of copper atoms in the copper layer 16 and of aluminum atoms in the aluminum layer 52.

Referring to FIG. 4 and FIG. 5, after the hole 20 is formed in the second dielectric layer 18, a first treating process is performed to treat the copper (Cu) layer 16 with a silicon-containing source such as silane (SiH₄) to form a CuSiₓ layer 501A on the copper (Cu) layer 16, and a second treating process is then performed to treat the CuSiₓ layer 501A with a nitrogen-containing source such as ammonia (NH₃), to form the CuSiN layer 501 on the copper (Cu) layer 16. Preferably, before the aluminum layer 52 is disposed in the recess 503, the wetting layer 56 can be formed on the barrier layer 50 by the deposition process, so as to enhance the connection of the second layer 24 and the aluminum layer 52.

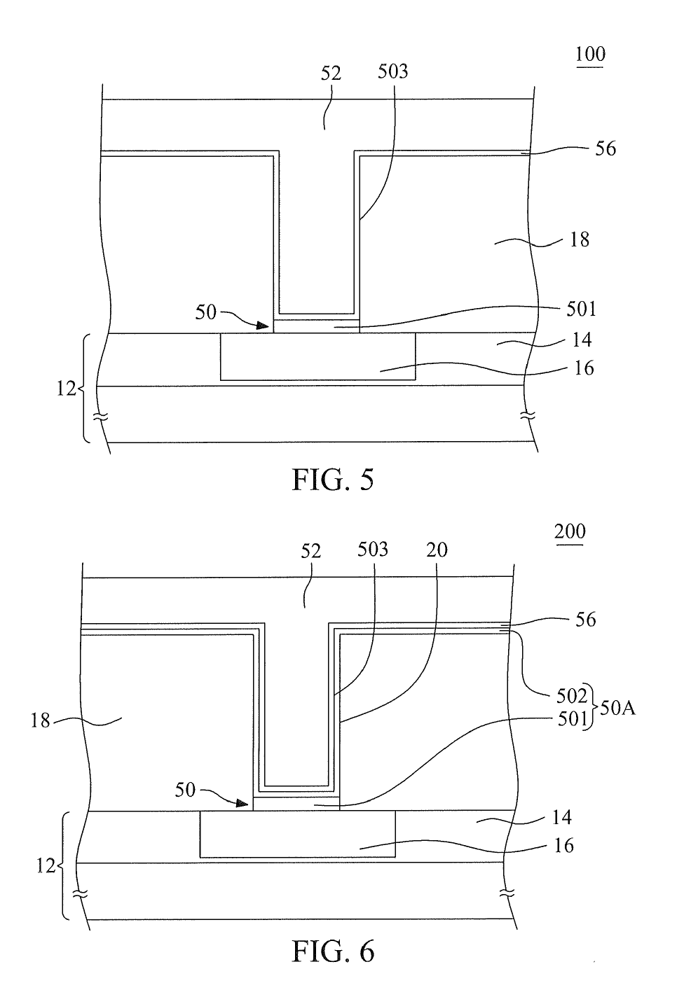

FIG. 6 is a schematic view illustrating another integrated circuit structure including a copper-aluminum interconnect with a barrier layer including a CuSiN layer according to one embodiment of the present invention. Referring to FIGS. 3, 4 and 6, after the hole 20 is formed in the second dielectric layer 18, a first treating process is performed to treat the copper (Cu) layer 16 with a silicon-containing source such as silane to form a CuSiₓ layer 501A on the copper (Cu) layer 16, and a second treating process is then performed to treat the CuSiₓ layer 501A with a nitrogen-containing source such as ammonia to form the CuSiN layer 501 on the copper (Cu) layer 16. Before the aluminum layer 52 is disposed in the recess 503, a titanium nitride (TiN) layer 502 is formed on the CuSiN layer 501 by the deposition process and a wetting layer 56 is then formed on the CuSiN layer 501 by the deposition process.

The titanium nitride (TiN) layer 502 is a good barrier for unbalanced diffusion of aluminum and can efficiently prevent diffusion of aluminum in the aluminum layer 52.

In the integrated circuit structure 100 including a barrier layer 50 which includes a CuSiN layer 501 according to one embodiment of the present invention, the CuSiN layer 501 can replace the traditional PVD barrier layer (such as Ti/TiN or Ta/TaN), thereby reducing the barrier thickness and mitigating the Al gap fill issues (via undercut, overhung, Al/Cu intermix, and poor via corner step coverage).

Although the present invention and its objectives have been described in detail, it should be understood that various changes, substitutions and alterations can be made herein without departing from the spirit and scope of the invention as defined by the appended claims. For example, many of the processes discussed above can be implemented through different methods and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit structure including a copper-aluminum interconnect, comprising:
a copper (Cu) layer;
a barrier layer including a CuSiN layer disposed on the copper layer;
an aluminum (Al) layer disposed over the barrier layer; and
a wetting layer disposed between the barrier layer and the aluminum (Al) layer.

2. The integrated circuit structure including a copper-aluminum to interconnect of claim 1, further comprising a dielectric layer disposed on the copper (Cu) layer, wherein the dielectric layer has a hole exposing the copper (Cu) layer, and the barrier layer covers the exposed copper (Cu) layer.

3. The integrated circuit structure including a copper-aluminum interconnect of claim 2, further comprising a substrate including a first dielectric layer and a second dielectric layer, wherein the copper layer is disposed in the first dielectric layer, the second dielectric layer is disposed on the first dielectric layer and the copper layer and forms a hole exposing the copper layer, and the barrier layer covers the exposed copper layer.

4. The integrated circuit structure including a copper-aluminum interconnect of claim 3, wherein the substrate further includes a silicon substrate, conductor and insulator below the first dielectric layer.

5. The integrated circuit structure including a copper-aluminum interconnect of claim 1, wherein the wetting layer is a titanium layer or a tantalum nitride layer.

6. The integrated circuit structure including a copper-aluminum interconnect of claim 1, wherein the barrier layer further comprising a titanium nitride layer, and the titanium nitride layer is disposed between the CuSiN layer and the wetting layer.

7. A method for fabricating an integrated circuit structure including a copper-aluminum interconnect, comprising the steps of:
providing a copper (Cu) layer;
forming a barrier layer including a CuSiN layer on the copper layer;
forming a wetting layer on the barrier layer; and
forming an aluminum (Al) layer on the wetting layer.

8. The method for fabricating an integrated circuit structure including a copper-aluminum interconnect of claim 7, wherein the forming process of the CuSiN layer of the barrier layer comprises the steps of:
performing a first treating process to treat the copper (Cu) layer with a silicon-containing source to form a CuSiₓ layer on the copper (Cu) layer; and
performing a second treating process to treat the CuSiₓ layer with a nitrogen-containing source to form the CuSiN layer on the copper (Cu) layer.

9. The method for fabricating an integrated circuit structure including a copper-aluminum interconnect of claim 8, wherein the silicon-containing source is silane.

10. The method for fabricating an integrated circuit structure including a copper-aluminum interconnect of claim 8, wherein the nitrogen-containing source is ammonia.

11. The method for fabricating an integrated circuit structure including a copper-aluminum interconnect of claim 7, wherein the forming process of the CuSiN layer of the barrier layer further comprises a step of forming a titanium nitride layer on the CuSiN layer before forming the wetting layer.

12. A method for fabricating an integrated circuit structure including a copper-aluminum interconnect, comprising the steps of:
forming a second dielectric layer on a first dielectric layer and a copper layer in the first dielectric layer to form a hole exposing the copper layer;
forming a barrier layer including a CuSiN layer on the exposed copper layer;
forming a wetting layer on the barrier layer; and
forming an aluminum (Al) layer in the hole and on the wetting layer.

13. The method for fabricating an integrated circuit structure including a copper-aluminum interconnect of claim 12, wherein the forming process of the CuSiN layer of the barrier layer comprises the steps of:
performing a first treating process to treat the copper (Cu) layer with a silicon-containing source to form a CuSiₓ layer on the copper (Cu) layer; and
performing a second treating process to treat the CuSiₓ layer with a nitrogen-containing source to form the CuSiN layer on the copper (Cu) layer.

14. The method for fabricating an integrated circuit structure including a copper-aluminum interconnect of claim 13, wherein the silicon-containing source is silane.

15. The method for fabricating an integrated circuit structure including a copper-aluminum interconnect of claim 13, wherein the nitrogen-containing source is ammonia.

16. The method for fabricating an integrated circuit structure including a copper-aluminum interconnect of claim 12, wherein the forming process of the CuSiN layer of the barrier layer further comprises a step of forming a titanium nitride layer on the CuSiN layer before forming the wetting layer.
